(19) United States
(12) Patent Application Publication
(10) Pub. No.: US 2012/0080083 A1
(43) Pub. Date: Apr. 5, 2012

(54) SEMICONDUCTOR ASSEMBLY WITH A METAL OXIDE LAYER HAVING INTERMEDIATE REFRACTIVE INDEX

(75) Inventors: Kathy J. Liang, Sunnyvale, CA (US); Gopalakrishna Prabhu, San Jose, CA (US); HienMinh Huu Le, San Jose, CA (US)

(73) Assignee: TWIN CREEKS TECHNOLOGIES, INC., San Jose, CA (US)

(21) Appl. No.: 12/894,254

(22) Filed: Sep. 30, 2010

(51) Int. Cl. H01L 31/0224; H01L 31/18

(52) U.S. Cl. 136/256; 438/69; 257/E31.126

(57) ABSTRACT

A semiconductor assembly is described with a thin metal oxide layer interposed between a transparent conductive oxide and an amorphous silicon layer, along with methods for making this structure. The metal oxide layer has a refractive index or range of refractive indices intermediate between that of the transparent conductive oxide and the amorphous silicon layer, and thus tends to reduce reflection at the interface. Such a layer can be used at the light-facing surface of a light-sensitive device such as a photovoltaic cell to maximize the amount of incident light entering the cell. Titanium oxide is a suitable metal oxide, and has a refractive index between those of silicon and of both indium tin oxide and aluminum-doped zinc oxide, two common transparent conductive oxides.

### BACKGROUND OF THE INVENTION

The invention relates to a structure to minimize reflection at a surface of a photosensitive device.

A conventional prior art photovoltaic cell includes a p-n diode; an example is shown in FIG. 1. A depletion zone forms at the p-n junction, creating an electric field. Incident photons (incident light is indicated by arrows) will knock electrons from the valence band to the conduction band, creating free electron-hole pairs. Within the electric field at the p-n junction, electrons tend to migrate toward the n region of the diode, while holes migrate toward the p region, resulting in current, called photocurrent. Typically the dopant concentration of one region will be higher than that of the other, so the junction is either a p+/n− junction (as shown in FIG. 1) or a n+/p− junction. The more lightly doped region is known as the base of the photovoltaic cell, while the more heavily doped region, of opposite conductivity type, is known as the emitter. Most carriers are generated within the base, and it is typically the thickest portion of the cell. The base and emitter together form the active region of the cell. The cell also frequently includes a heavily doped contact region in electrical contact with the base, and of the same conductivity type, to improve current flow. In the example shown in FIG. 1, the heavily doped contact region is n-type.

Any light reflected at the light-facing surface of the cell will not be absorbed, and thus will not contribute to photocurrent. To reduce reflection at the light-facing surface, many photovoltaic cells include an antireflective coating. Photovoltaic cells are most commonly formed of silicon, and in some cells, the light-facing surface of the cell includes an amorphous silicon layer. Because amorphous silicon is typically less conductive than crystalline silicon, generally a transparent conductive oxide (TCO) is used as an antireflective coating with amorphous silicon. The refractive index of both indium tin oxide (ITO) and aluminum-doped oxide (AZO), two of the most common TCOs, is about 2. The refractive index of silicon is about 3. Reflection is prone to occur at any interface between materials having different refractive indices. The greater the difference in refractive indices across an interface, the more light is lost at that interface due to reflection.

### SUMMARY OF THE INVENTION

The present invention is defined by the following claims, and nothing in this section should be taken as a limitation on those claims. In general, the invention is directed to a structure to reduce reflection of light at the light-facing surface of a photosensitive device such as a photovoltaic cell.

A first aspect of the invention provides for a semiconductor assembly comprising a layer of transparent conductive oxide having a first refractive index, the transparent conductive oxide having a thickness between about 800 and about 2000 angstroms; a layer of amorphous silicon having a second refractive index, wherein the amorphous silicon layer is part of a photovoltaic cell or provides electrical contact to a photovoltaic cell; and a layer of metal oxide having a third refractive index or range of refractive indices, the metal oxide layer disposed between and in immediate contact with the transparent conductive oxide layer and the amorphous silicon layer, wherein the third refractive index or range of refractive indices is between the first refractive index and the second refractive index, and wherein the layer of metal oxide has a thickness less than about 300 angstroms.

Another aspect of the invention provides for a method to form a semiconductor assembly, the method comprising: forming an amorphous silicon layer, the amorphous silicon layer having a first refractive index; forming a metal oxide layer on and in immediate contact with the amorphous silicon layer, the metal oxide layer having a second refractive index or range of refractive indices, wherein the metal oxide layer has a thickness less than about 300 angstroms; and forming a transparent conductive oxide layer on and in immediate contact with the metal oxide layer, the transparent conductive oxide layer having a third refractive index, wherein the transparent conductive oxide layer has a thickness between about 800 and about 2000 angstroms, wherein the second refractive index or range of refractive indices is between the first refractive index and the third refractive index, and wherein the semiconductor assembly comprises a photovoltaic cell.

Each of the aspects and embodiments of the invention described herein can be used alone or in combination with one another.

The preferred aspects and embodiments will now be described with reference to the attached drawings.

### BRIEF DESCRIPTION OF THE DRAWINGS

FIG. 1 is a cross-sectional view of a prior art photovoltaic cell.

FIGS. 2a is a cross-sectional view illustrating refraction of light at the interface of a transparent conductive oxide and amorphous silicon. FIG. 2b is a cross-sectional view illustrating refraction of light with an interposed metal oxide layer, according to embodiments of the present invention.

FIGS. 3a-3d are cross-sectional views showing stages of fabrication of a photovoltaic cell formed according to an embodiment of U.S. patent application Ser. No. 12/026,530.

FIG. 4 is a flow chart listing steps involved in fabrication a structure according to embodiments of the present invention.

FIGS. 5a-5e are cross-sectional views showing stages of fabrication of a photovoltaic cell formed according to an embodiment of the present invention.

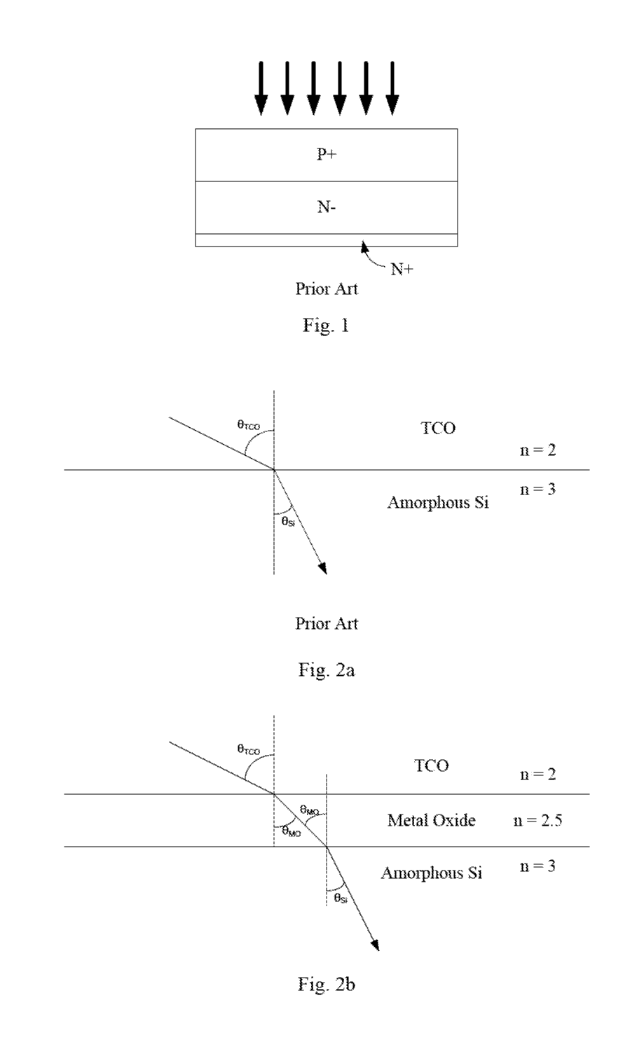

### DETAILED DESCRIPTION OF THE EMBODIMENTS

In the present invention, a thin layer of a metal oxide having a refractive index intermediate between these two refractive indices is interposed between them. The efficiency of a photovoltaic cell is decreased when incident light at the light-facing surface of the cell is reflected. The structure of the present invention minimizes reflection to increase efficiency and thus increase energy output from a photovoltaic cell.

FIG. 2a shows an interface between a material having a refractive index n=2, such as a layer of ITO, and a layer of amorphous silicon, having a refractive index n=3, as in prior art photovoltaic cells. Some light travelling in the ITO at angle θ_{ITO} measured from vertical will be refracted at the interface, and will continue through the amorphous silicon layer at angle θ_{Si}. Due to this relatively large change in refractive index, some fraction of light will be reflected at this interface. FIG. 2b shows an embodiment of the present invention, in which a thin metal oxide layer, in this example having a refractive index of 2.5, is interposed between the TCO layer and the amorphous silicon layer. Some incident light travelling in the ITO at angle θ_{ITO} is refracted at the interface with the metal oxide layer to angle θ_{MO}, and when that light reaches the interface with the amorphous silicon layer, it is refracted again to angle θ_{Si}. Less light is reflected at these two interfaces having smaller refractive index mismatches than at the single interface of FIG. 2a with a larger refractive index.

Note that refractive index varies with the wavelength of light. For photovoltaic devices, the wavelengths of interest are between about 300 and about 1100 nm. The refractive indices referred to in this discussion are those for wavelengths of about 650 nm.

A metal oxide having a suitable index of refraction is titanium oxide. Titanium oxide may take several forms, including TiO, Ti₂O₃, TiO₂, TiO₃, and others. The term “titanium oxide” and the notation TiO will be understood to indicate any compound consisting essentially of titanium and oxygen. The refractive index of titanium oxide varies, depending on its composition. In general, titanium oxide has only limited conductivity and transparency, so this layer is generally kept thin, for example about 300 angstroms or less. Other suitable metal oxides may include magnesium oxide and zinc oxide. In some embodiments, it may be preferred to form a graded metal oxide, where the composition of the metal oxide, and thus its refractive index, varies across the thickness of the film, avoiding any sudden transition in refractive index in the path of incident light at the light-facing surface.

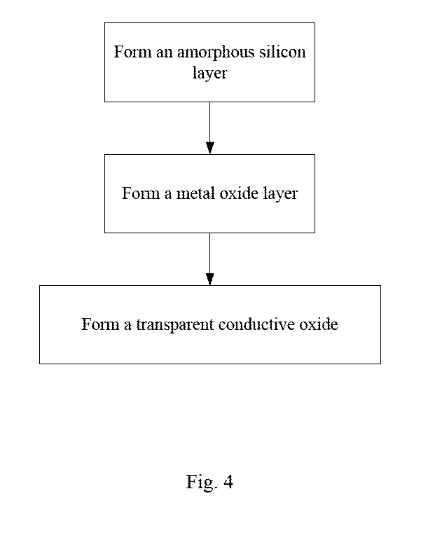

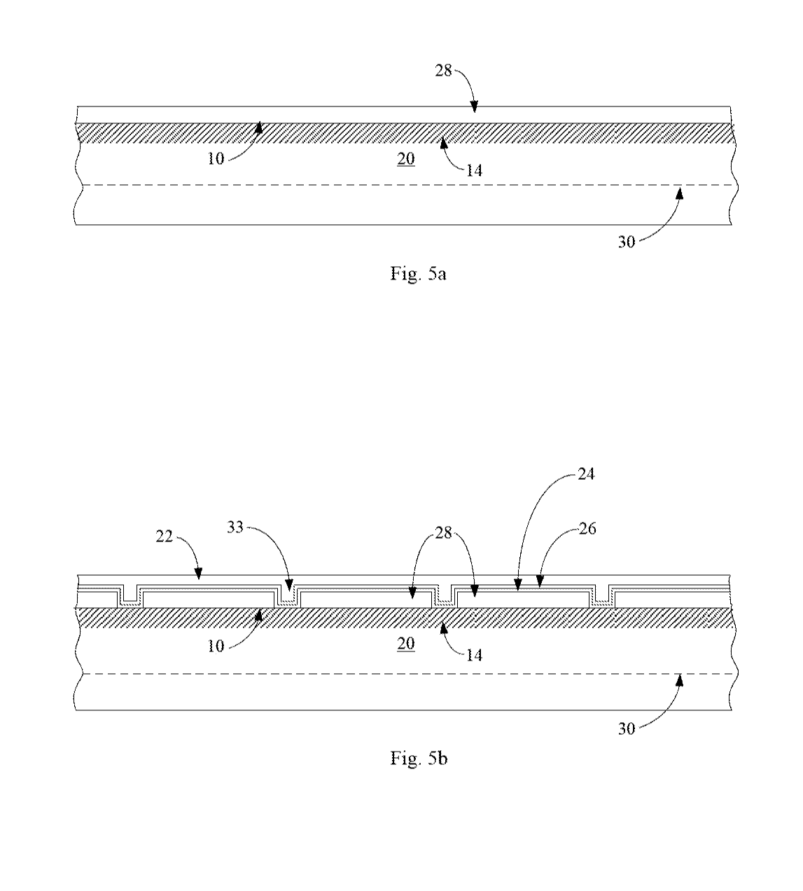

Summarizing, a structure to reduce reflected light at the surface of a photovoltaic assembly can be formed by a method comprising: forming an amorphous silicon layer, the amorphous silicon layer having a first refractive index; forming a metal oxide layer on and in immediate contact with the amorphous silicon layer, the metal oxide layer having a second refractive index or range of refractive indices, wherein the metal oxide layer has a thickness less than about 300 angstroms; and forming a transparent conductive oxide layer on and in immediate contact with the metal oxide layer, the transparent conductive oxide layer having a third refractive index, wherein the transparent conductive oxide layer has a thickness between about 800 and about 2000 angstroms, wherein the second refractive index or range of refractive indices is between the first refractive index and the third refractive index, and wherein the photovoltaic assembly comprises a photovoltaic cell. These steps are summarized in the flow chart of FIG. 4.

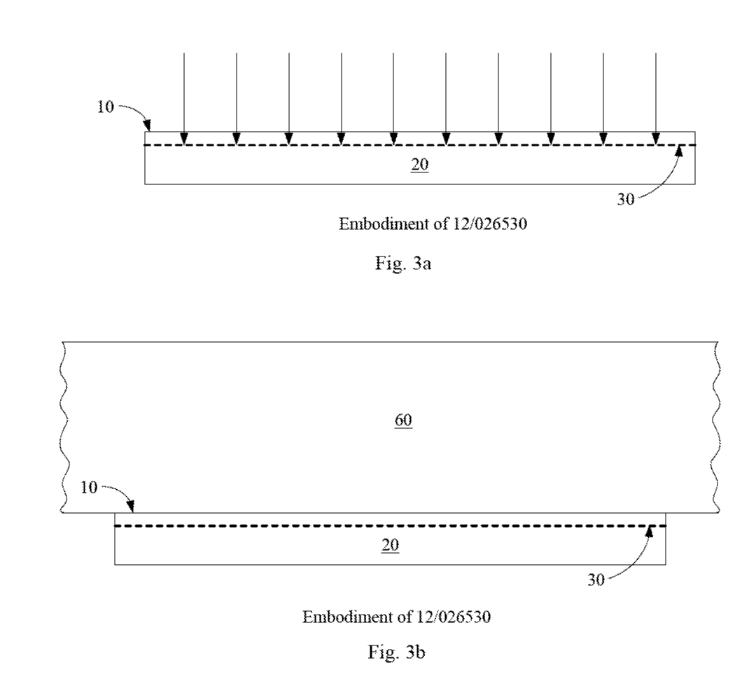

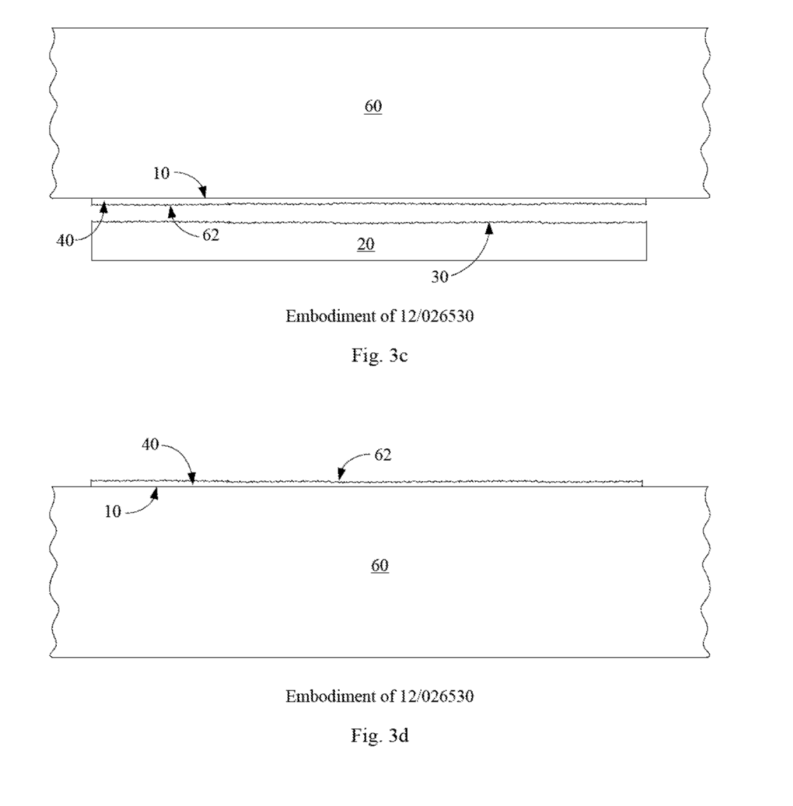

Sivaram et al., U.S. patent application Ser. No. 12/026,530, “Method to Form a Photovoltaic Cell Comprising a Thin Lamina,” filed Feb. 5, 2008, owned by the assignee of the present invention and hereby incorporated by reference, describes fabrication of a photovoltaic cell comprising a thin semiconductor lamina formed of non-deposited semiconductor material. Referring to FIG. 3a, in embodiments of Sivaram et al., a semiconductor donor wafer 20 is implanted through first surface 10 with one or more species of gas ions, for example hydrogen and/or helium ions. The implanted ions define a cleave plane 30 within the semiconductor donor wafer. As shown in FIG. 3b, donor wafer 20 is affixed at first surface 10 to receiver 60. Referring to FIG. 3c, an anneal causes lamina 40 to cleave from donor wafer 20 at cleave plane 30, creating second surface 62. In embodiments of Sivaram et al., additional processing before and after the cleaving step forms a photovoltaic cell comprising semiconductor lamina 40, which is between about 0.2 and about 100 microns thick, for example between about 0.2 and about 50 microns, for example between about 1 and about 20 microns thick, in some embodiments between about 1 and about 10 microns thick or between about 5 and about 15 microns thick, though any thickness within the named range is possible. FIG. 3d shows the structure inverted, with receiver 60 at the bottom, as during operation in some embodiments. Receiver 60 may be a discrete receiver element having a maximum width no more than 50 percent greater than that of donor wafer 10, and preferably about the same width, as described in Herner, U.S. patent application Ser. No. 12/057,265, “Method to Form a Photovoltaic Cell Comprising a Thin Lamina Bonded to a Discrete Receiver Element,” filed on Mar. 27, 2008, owned by the assignee of the present application and hereby incorporated by reference. Alternatively, a plurality of donor wafers may be affixed to a single, larger receiver, and a lamina cleaved from each donor wafer.

Using the methods of Sivaram et al., photovoltaic cells, rather than being formed from sliced wafers, are formed of thin semiconductor laminae without wasting silicon through kerf loss or by fabrication of an unnecessarily thick cell, thus reducing cost. The same donor wafer can be reused to form multiple laminae, further reducing cost, and may be resold after exfoliation of multiple laminae for some other use.

A layer of a metal oxide disposed between a TCO and an amorphous silicon layer can reduce reflection and improve efficiency of any photovoltaic cell. A cell produced using the methods of Sivaram et al. will have a very thin silicon layer for absorbing light; thus reducing reflection may be particularly important, and methods of the present invention may be particularly advantageous.

For clarity, a detailed example of a photovoltaic assembly including a lamina having thickness between 0.2 and 100 microns, in which a metal oxide layer having a suitable refractive index is interposed between a TCO and an amorphous silicon layer at the light-facing surface, according to embodiments of the present invention, will be provided. For completeness, many materials, conditions, and steps will be described. It will be understood, however, that many of these details can be modified, augmented, or omitted while the results fall within the scope of the invention.

### Example

The process begins with a donor body of an appropriate semiconductor material. An appropriate donor body may be a monocrystalline silicon wafer of any practical thickness, for example from about 200 to about 1000 microns thick. Typically the wafer has a <100> orientation, though wafers of other orientations may be used. In alternative embodiments, the donor wafer may be thicker; maximum thickness is limited only by practicalities of wafer handling. Alternatively, polycrystalline or multicrystalline silicon may be used, as may microcrystalline silicon, or wafers or ingots of other semiconductor materials, including germanium, silicon germanium, or III-V or II-VI semiconductor compounds such as GaAs, InP, etc. In this context the term multicrystalline typically refers to semiconductor material having grains that are on the order of a millimeter or larger in size, while polycrystalline semiconductor material has smaller grains, on the order of a thousand angstroms. The grains of microcrystalline semiconductor material are very small, for example 100 angstroms or so. Microcrystalline silicon, for example, may be fully crystalline or may include these microcrystals in an amorphous matrix. Multicrystalline or polycrystalline semiconductors are understood to be completely or substantially crystalline. It will be appreciated by those skilled in the art that the term “monocrystalline silicon” as it is customarily used will not exclude silicon with occasional flaws or impurities such as conductivity-enhancing dopants.

The process of forming monocrystalline silicon generally results in circular wafers, but the donor body can have other shapes as well. For photovoltaic applications, cylindrical monocrystalline ingots are often machined to an octagonal, or pseudosquare, cross section prior to cutting wafers. Wafers may also be other shapes, such as square. Square wafers have the advantage that, unlike circular or hexagonal wafers, they can be aligned edge-to-edge on a photovoltaic module with minimal unused gaps between them. The diameter or width of the wafer may be any standard or custom size. For simplicity this discussion will describe the use of a monocrystalline silicon wafer as the semiconductor donor body, but it will be understood that donor bodies of other types and materials can be used.

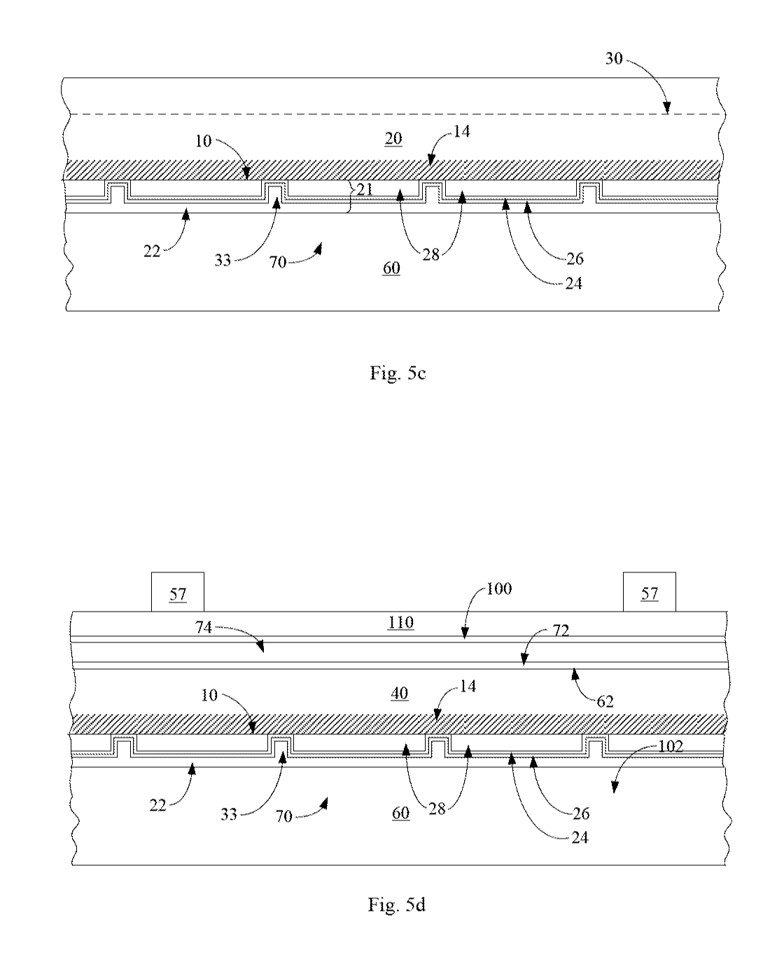

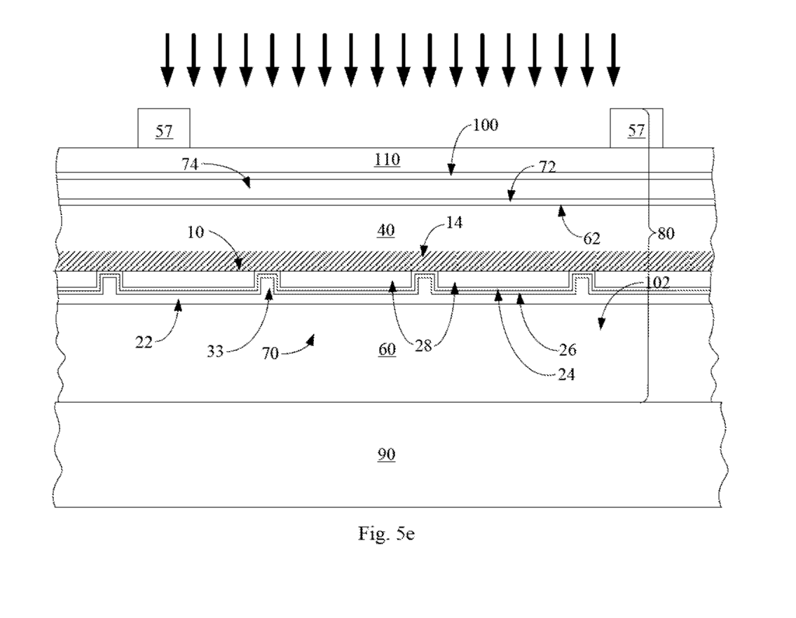

Referring to FIG. 5a, donor wafer 20 is a monocrystalline silicon wafer which is lightly to moderately doped to a first conductivity type. The present example will describe a relatively lightly n-doped wafer 20 but it will be understood that in this and other embodiments the dopant types can be reversed. Wafer 20 may be doped to a concentration of between about 1×10¹⁵ and about 1×10¹⁸ dopant atoms/cm³, for example about 1×10¹⁷ dopant atoms/cm³. Donor wafer 20 may be, for example, solar- or semiconductor-grade silicon.

First surface 10 may be heavily doped to some depth to the same conductivity type as wafer 20, forming heavily doped region 14; in this example, heavily doped region 14 is n-type. This doping step can be performed by any conventional method, including diffusion doping. Any conventional n-type dopant may be used, such as phosphorus or arsenic. Dopant concentration may be as desired, for example at least 1×10¹⁸ dopant atoms/cm³, for example between about 1×10¹⁸ and 1×10²¹ dopant atoms/cm³. Doping and texturing can be performed in any order, but since most texturing methods remove some thickness of silicon, it may be preferred to form heavily doped n-type region 14 following texturing. Heavily doped region 14 will provide electrical contact to the base region in the completed device. In an alternative embodiment, heavily doped region 14 can be p-type, forming a p-n junction between heavily doped region 14 and the rest of lightly doped wafer 20. In this alternative embodiment, heavily doped region 14 will be the emitter of the cell to be formed.

Next, in the present embodiment, a dielectric layer 28 is formed on first surface 10. As will be seen, in the present example first surface 10 will be the back of the completed photovoltaic cell, and a conductive material is to be formed on dielectric layer 28. The reflectivity of the conductive layer to be formed is enhanced if dielectric layer 28 is relatively thick. For example, if dielectric layer 28 is silicon dioxide, it may be between about 1000 and about 2000 angstroms thick, while if dielectric layer 28 is silicon nitride, it may be between about 700 and about 800 angstroms thick, for example about 750 angstroms. This layer may be grown or deposited by any suitable method. A grown oxide or nitride layer 28 passivates first surface 10 better than if this layer is deposited. In some embodiments, a first thickness of dielectric layer 28 may be grown, while the rest is deposited.

Turning to FIG. 5b, in the next step, ions, preferably hydrogen or a combination of hydrogen and helium, are implanted into wafer 20 through first surface 10 to define cleave plane 30, as described earlier. This implant may be performed using the teachings of Parrill et al., U.S. patent application Ser. No. 12/122,108, “Ion Implanter for Photovoltaic Cell Fabrication,” filed May 16, 2008; or those of Ryding et al., U.S. patent application Ser. No. 12/494,268, “Ion Implantation Apparatus and a Method for Fluid Cooling,” filed Jun. 30, 2009; or of Purser et al. U.S. patent application Ser. No. 12/621,689, “Method and Apparatus for Modifying a Ribbon-Shaped Ion Beam,” filed Nov. 19, 2009, all owned by the assignee of the present invention and hereby incorporated by reference. The overall depth of cleave plane 30 is determined by several factors, including implant energy. The depth of cleave plane 30 can be between about 0.2 and about 100 microns from first surface 10, for example between about 0.5 and about 20 or about 50 microns, for example between about 1 and about 10 microns, between about 1 or 2 microns and about 5 or 6 microns, or between about 4 and about 8 microns. Alternatively, the depth of cleave plane 30 can be between about 5 and about 15 microns, for example about 11 or 12 microns.

Still referring to FIG. 5b, after implant, openings 33 are formed in dielectric layer 28 by any appropriate method, for example by laser scribing or screen printing an etchant paste. The size of openings 33 may be as desired, and will vary with dopant concentration, metal used for contacts, etc. In one embodiment, these openings may be about 40 microns square. Note that figures are not to scale.

A conductive layer 24 is formed on dielectric layer 28 by any suitable method, for example by sputtering or thermal evaporation. Conductive layer 24 should be conductive, reflective, and able to tolerate relatively high temperatures to follow. Titanium is a suitable choice, with the additional advantage that, during subsequent heating steps, titanium in contact with silicon in openings 33 will form titanium silicide, providing a good electrical contact. This layer may have any desired thickness, for example between about 30 and about 400 angstroms, in some embodiments about 200 angstroms thick or less, for example about 50 angstroms. Layer 24 may be titanium, cobalt or an alloy thereof, for example, an alloy which is at least 80 or 90 atomic percent titanium or cobalt. Titanium layer 24 is in immediate contact with first surface 10 of donor wafer 20 through openings 33 in dielectric layer 28; elsewhere it contacts dielectric layer 28. In alternative embodiments, dielectric layer 28 is omitted, and titanium layer 24 is formed in immediate contact with donor wafer 20 at all points of first surface 10.

Non-reactive barrier layer 26 is formed on and in immediate contact with titanium layer 24. This layer is formed by any suitable method, for example by sputtering or thermal evaporation. Non-reactive barrier layer 26 may be any material, or stack of materials, that will not react with silicon, is conductive, and will tolerate the higher temperatures used in subsequent processing. Suitable materials for non-reactive barrier layer include Mo, W, TiN, TiW, TiO, Ta, TaN, TaO, TaSiN, Zr, or alloys thereof. The thickness of non-reactive barrier layer 26 may range from, for example, between about 50 and about 200 angstroms, for example between about 50 and about 100 angstroms. In some embodiments this layer is about 100 angstroms thick.

Low-resistance layer 22 is formed on non-reactive barrier layer 26. This layer may be, for example, titanium, cobalt, silver, or tungsten or alloys thereof. In this example low-resistance layer 22 is titanium or an alloy that is at least 80 or 90 atomic percent titanium, formed by any suitable method. Titanium layer 22 may be between about 500 and about 10,000 angstroms (1 micron) thick, for example about 3000 angstroms thick.

A Ti—Mo—Ti stack including layers 24, 26, and 22 has been described. In other embodiments there may be multiple thin layers of the non-reactive barrier material, in this example Mo, interposed with the other conductive layers, for example a Ti—Mo—Ti—Mo—Ti stack.

Referring to FIG. 5c, next a receiver element adhered to the donor wafer is provided. The figure shows the structure inverted with receiver element 60 on the bottom. This receiver element 60 will provide structural support to the thin lamina to be cleaved from donor wafer 20 at cleave plane 30. As described by Sivaram et al., this receiver element can be a rigid or semi-rigid material, such as glass, metal, semiconductor, etc., which is bonded to donor wafer 20. In this example the intermetal stack 21 is disposed between donor wafer 20 and the receiver element. Alternatively, a receiver element can be constructed by applying or accreting a material or stack of materials to first surface 10, or, in the example described, to a layer on or above first surface 10, such as adhesion layer 32, as described in Agarwal et al., U.S. patent application Ser. No. 12/826,762, “A Formed Ceramic Receiver Element Adhered to a Semiconductor Lamina,” filed Jun. 30, 2010, owned by the assignee of the present application and hereby incorporated by reference.

Receiver element 60 may be about the same size as donor wafer 20, or slightly larger, or slightly smaller, and may or may not be the same shape. In some embodiments, receiver element 60 has a much larger area than donor wafer 20, and a plurality of donor wafers are affixed, side-by-side, to a single receiver element 60. Receiver element 60 is provided adhered to donor wafer 20, with dielectric layer 28, titanium layer 24, non-reactive barrier layer 26, and low-resistance layer 22 intervening. Receiver element 60 may be a laminate structure, including layers of different materials.

Referring to FIG. 5d, a thermal step causes lamina 40 to cleave from the donor wafer at the cleave plane. Cleaving is achieved in this example by exfoliation, which may be achieved at temperatures between, for example, about 350 and about 650 degrees C. In general, exfoliation proceeds more rapidly at higher temperature. The thickness of lamina 40 is determined by the depth of cleave plane 30. In many embodiments, the thickness of lamina 40 is between about 1 and about 10 microns, for example between about 2 and about 5 microns, for example about 4.5 microns. In other embodiments, the thickness of lamina 40 is between about 4 and about 20 microns, for example between about 10 and about 15 microns, for example about 11 microns.

During relatively high-temperature steps, such as the exfoliation of lamina 40, the portions of titanium layer 24 in immediate contact with silicon lamina 40 will react to form titanium silicide. If dielectric layer 28 was included, titanium silicide is formed where first surface 10 of lamina 40 was exposed in vias 33. If dielectric layer 28 was omitted, in general all of the titanium of titanium layer 24 will be consumed, forming a blanket of titanium silicide.

Second surface 62 has been created by exfoliation. At this point texturing can be created at second surface 62 according to embodiments of the present invention. A standard clean is performed at second surface 62, for example by hydrofluoric acid.

A method for forming advantageous low-relief texture is disclosed in Li et al., U.S. patent application Ser. No. 12/729,878, “Creation of Low-Relief Texture for a Photovoltaic Cell,” filed Mar. 23, 2010, owned by the assignee of the present invention and hereby incorporated by reference.

In some embodiments, an anneal may be performed to repair damage caused to the crystal lattice throughout the body of lamina 40 during the implant step. Annealing may be performed, for example, at 500 degrees C. or greater, for example at 550, 600, 650, 700, 800, 850 degrees C. or greater, at about 950 degrees C. or more. The structure may be annealed, for example, at about 650 degrees C. for about 45 minutes, or at about 800 degrees for about two minutes, or at about 950 degrees for 60 seconds or less. In many embodiments the temperature exceeds 900 degrees C. for at least 30 seconds. In other embodiments, no damage anneal is performed.

Referring to FIG. 5d, if any native oxide (not shown) has formed on second surface 62 during annealing, it may be removed by any conventional cleaning step, for example by hydrofluoric acid. After cleaning, a silicon layer is deposited on second surface 62. This layer 74 includes heavily doped silicon, and is amorphous silicon. This layer or stack may have a thickness, for example, between about 50 and about 350 angstroms. FIG. 5d shows an embodiment that includes intrinsic or nearly intrinsic amorphous silicon layer 72 between second surface 62 and doped layer 74, and in contact with both. In other embodiments, layer 72 may be omitted. In this example, heavily doped silicon layer 74 is heavily doped p-type, opposite the conductivity type of lightly doped n-type lamina 40, and serves as the emitter of the photovoltaic cell being formed, while lightly doped n-type lamina 40 comprises the base region. If included, layer 72 is sufficiently thin that it does not impede electrical connection between lamina 40 and doped silicon layer 74. Note that in general deposited amorphous silicon is conformal; thus any texture at surface 62 is reproduced at the surfaces of silicon layers 72 and 74.

The refractive index of amorphous silicon layer 74 is about 3. Next a layer 100 of titanium oxide is formed on and in immediate contact with amorphous silicon layer 74. This layer should be about 300 angstroms thick or less, for example between about 10 or 20 angstroms and about 300 angstroms, for example between about 10 angstroms and about 100 angstroms, for example between about 20 angstroms and about 100 angstroms. Titanium oxide layer 100 may be TiO, Ti₂O₃, TiO₂, TiO₃, or some other titanium oxide compound. The refractive index of titanium oxide layer 100 is less than that of amorphous silicon and greater than that of the TCO layer that will be formed next; this refractive index is between about 2 and about 3, for example between about 2.2 and about 2.8. The refractive index of titanium oxide can be varied by changing its characteristics; for example, in general, a higher ratio of oxygen to titanium correlates to a higher refractive index. In some embodiments, the refractive index of titanium oxide layer 100 may vary across the thickness of the layer, ie. the layer may have a range of refractive indices. The range of refractive indices will be between the refractive index of amorphous silicon and that of the TCO to be formed. The refractive index of titanium oxide layer 100 will generally be higher adjacent to amorphous silicon layer 74, and lower adjacent to the TCO layer to be formed. For example, titanium oxide layer 100 can consist of two, three or more distinct sub-layers, each with a progressively smaller refractive index, the highest refractive index on the bottom, adjacent to amorphous silicon layer 74, and the lowest formed last, at the top of the stack. The oxygen to titanium ration may be highest adjacent amorphous silicon layer 74 and lowest adjacent to TCO layer 110. Even when formed of two, three, or more sub-layers, the total thickness of metal oxide layer 100 will not exceed about 300 angstroms. In other embodiments, other metal oxides having suitable refractive indices may be used instead of titanium oxide or may be combined with titanium oxide layers.

Titanium oxide layer 100 can be formed by any suitable method, for example by chemical vapor deposition (CVD) or physical vapor deposition (PVD). It has been found that a titianium oxide layer formed by sputtering (a form of PVD) may include fewer contaminants than one formed by CVD, since the sputtering process produces no chemical byproducts. Chemical byproducts are produced by CVD, and generally will be incorporated into the titanium oxide layer.

In some embodiments, titanium oxide layer 100 is created by reactive sputtering using a titanium target while flowing oxygen and argon. The ratio of titanium to oxygen in the resulting oxide can be varied by varying the relative flow of the gases. For example, Ar and O₂ may be flowed. In order to vary the proportion of oxygen in titanium oxide layer 100, the flow of O₂ may be varied from, for example 5 percent to 40 percent of total flow.

During reactive sputtering, a thickness of the titanium oxide may form on the target surface. If this insulating layer becomes sufficiently thick, positive argon atoms are no longer attracted to the surface, and sputtering slows or stops. As is known to those skilled in the art, regular pulsing of the power supply serves to discharge any accumulated charge at the target surface, preventing excessive buildup.

A transparent conductive oxide (TCO) layer 110 is formed on and in immediate contact with titanium oxide layer 100. Appropriate materials for TCO 110 include indium tin oxide and aluminum-doped zinc oxide. This layer may be, for example, about between about 800 to about 2500 angstroms thick, for example about 1000 to about 2000 angstroms thick, and serves as both a top electrode and an antireflective layer. In alternative embodiments, an additional antireflective layer (not shown) may be formed on top of TCO 110.

A photovoltaic cell has been formed, including lightly doped n-type lamina 40, which comprises the base of the cell, and heavily doped p-type amorphous silicon layer 74, which serves as the emitter of the cell. Heavily doped n-type region 14 will provide good electrical contact to the base region of the cell. Electrical contact must be made to both faces of the cell. Contact to emitter 74 is made, for example, by gridlines 57. If receiver element 60 is conductive, it has been formed in electrical contact with heavily doped region 14 by way of conductive layers 24, 26, and 22.

If receiver element 60 is not conductive, electrical contact to heavily doped region 14 can be formed using a variety of methods, including those described in Petti et al., U.S. patent application Ser. No. 12/331,376, “Front Connected Photovoltaic Assembly and Associated Methods,” filed Dec. 9, 2008; and Petti et al., U.S. patent application Ser. No. 12/407,064, “Method to Make Electrical Contact to a Bonded Face of a Photovoltaic Cell,” filed Mar. 19, 2009, hereinafter the '064 application, both owned by the assignee of the present application and both hereby incorporated by reference.

FIG. 5e shows completed photovoltaic assembly 80, which includes a photovoltaic cell and receiver element 60. In alternative embodiments, by changing the dopants used, heavily doped region 14 may serve as the emitter, at first surface 10, while heavily doped silicon layer 74 serves as a contact to the base region. Incident light (indicated by arrows) falls on TCO 110, passes through titanium oxide layer 100, enters the cell at heavily doped p-type amorphous silicon layer 74, enters lamina 40 at second surface 62, and travels through lamina 40. Reflective layer 24 will serve to reflect some light back into the cell. In this embodiment, receiver element 60 serves as a substrate. Receiver element 60 and lamina 40, and associated layers, form a photovoltaic assembly 80. Multiple photovoltaic assemblies 80 can be formed and affixed to a supporting substrate 90 or, alternatively, a supporting superstrate (not shown). Each photovoltaic assembly 80 includes a photovoltaic cell. The photovoltaic cells of a module are generally electrically connected in series.

In the present example, the body of lamina 40, which serves as the base region of the cell, was lightly doped n-type, amorphous silicon layer 74 at second surface 62 was heavily doped p-type, forming the emitter of the cell, and heavily doped region 14, at first surface 10, was heavily doped n-type, providing a base contact region. In alternative embodiments all polarities could be reversed. In either case, note that amorphous silicon layer 74 is heavily doped and is either an emitter of the photovoltaic cell or a base contact of the photovoltaic cell, while the base of the photovoltaic cell is monocrystalline silicon.

To summarize, what has been described is a semiconductor assembly comprising: a layer of transparent conductive oxide having a first refractive index, the transparent conductive oxide having a thickness between about 800 and about 2000 angstroms; a layer of amorphous silicon having a second refractive index, wherein the amorphous silicon layer is part of a photovoltaic cell or provides electrical contact to a photovoltaic cell; and a layer of metal oxide having a third refractive index or range of refractive indices, the metal oxide layer disposed between and in immediate contact with the transparent conductive oxide layer and the amorphous silicon layer, wherein the third refractive index or range of refractive indices is between the first refractive index and the second refractive index, and wherein the layer of metal oxide has a thickness less than about 300 angstroms.

A variety of embodiments has been provided for clarity and completeness. Clearly it is impractical to list all possible embodiments. Other embodiments of the invention will be apparent to one of ordinary skill in the art when informed by the present specification. Detailed methods of fabrication have been described herein, but any other methods that form the same structures can be used while the results fall within the scope of the invention.

The foregoing detailed description has described only a few of the many forms that this invention can take. For this reason, this detailed description is intended by way of illustration, and not by way of limitation. It is only the following claims, including all equivalents, which are intended to define the scope of this invention.

What is claimed is:

1. A semiconductor assembly comprising:
a layer of transparent conductive oxide having a first refractive index, the transparent conductive oxide having a thickness between about 800 and about 2000 angstroms;
a layer of amorphous silicon having a second refractive index, wherein the amorphous silicon layer is part of a photovoltaic cell or provides electrical contact to a photovoltaic cell; and
a layer of metal oxide having a third refractive index or range of refractive indices, the metal oxide layer disposed between and in immediate contact with the transparent conductive oxide layer and the amorphous silicon layer,
wherein the third refractive index or range of refractive indices is between the first refractive index and the second refractive index, and
wherein the layer of metal oxide has a thickness less than about 300 angstroms.

2. The semiconductor assembly of claim 1 wherein the metal oxide layer is titanium oxide, magnesium oxide, or zinc oxide.

3. The semiconductor assembly of claim 2 wherein the metal oxide layer is titanium oxide.

4. The semiconductor assembly of claim 3 wherein, within the metal oxide layer, the ratio of oxygen to titanium is higher adjacent to the amorphous silicon layer than the ratio of oxygen to titanium adjacent to the transparent conductive oxide layer.

5. The semiconductor assembly of claim 1 wherein the transparent conductive oxide layer is indium tin oxide or aluminum-doped zinc oxide.

6. The semiconductor assembly of claim 1 wherein the metal oxide layer has a range of refractive indices, wherein the refractive index of the metal oxide layer is greater adjacent the amorphous silicon layer than the refractive index of the metal oxide adjacent the transparent conductive oxide layer.

7. The semiconductor assembly of claim 1 wherein the amorphous silicon layer is an emitter of the photovoltaic cell.

8. The semiconductor assembly of claim 1 wherein the photovoltaic cell comprises a monocrystalline silicon lamina having a thickness between about 2 and about 20 microns.

9. The semiconductor assembly of claim 8 wherein the lamina comprises a base of the photovoltaic cell.

10. The semiconductor assembly of claim wherein the metal oxide layer has a thickness between about 10 and about 100 angstroms.

11. The semiconductor assembly of claim 1 wherein the amorphous silicon layer is heavily doped and is in contact with an intrinsic or nearly intrinsic amorphous silicon layer.

12. The semiconductor assembly of claim 1 wherein the amorphous silicon layer is heavily doped and is either an emitter of the photovoltaic cell or a base contact of the photovoltaic cell, wherein a base of the photovoltaic cell is monocrystalline silicon.

13. The semiconductor assembly of claim 1 wherein the metal oxide layer is formed by reactive sputtering.

14. A method to form a semiconductor assembly, the method comprising:
forming an amorphous silicon layer, the amorphous silicon layer having a first refractive index;
forming a metal oxide layer on and in immediate contact with the amorphous silicon layer, the metal oxide layer having a second refractive index or range of refractive indices, wherein the metal oxide layer has a thickness less than about 300 angstroms; and
forming a transparent conductive oxide layer on and in immediate contact with the metal oxide layer, the transparent conductive oxide layer having a third refractive index, wherein the transparent conductive oxide layer has a thickness between about 800 and about 2000 angstroms,
wherein the second refractive index or range of refractive indices is between the first refractive index and the third refractive index, and
wherein the semiconductor assembly comprises a photovoltaic cell.

15. The method of claim 14 wherein the metal oxide layer is titanium oxide, and wherein the step of forming the metal oxide layer is performed by physical vapor deposition.

16. The method of claim 15 wherein the amorphous silicon layer is heavily doped.

17. The method of claim 16 wherein the amorphous silicon layer comprises an emitter or a base contact of the photovoltaic cell, and wherein a monocrystalline silicon lamina comprises a base of the photovoltaic cell.
